(19) United States
(12) Patent Application Publication
(10) Pub. No.: US 2024/0273250 A1
(43) Pub. Date: Aug. 15, 2024

(54) BRIDGE RENEWAL METHOD AND SUPPORT SYSTEM

(71) Applicants: OBAYASHI CORPORATION, Tokyo (JP); OFFICE K1 CO., LTD., Osaka-shi, Osaka (JP)

(72) Inventors: Kazumasa HIGURE, Tokyo (JP); Kenji MITAMURA, Tokyo (JP); Keiichi YASUDA, Osaka-shi (JP)

(73) Assignees: OBAYASHI CORPORATION, Tokyo (JP); OFFICE K1 CO., LTD., Osaka-shi, Osaka (JP)

(21) Appl. No.: 18/292,842

(22) PCT Filed: Jun. 15, 2023
(86) PCT No.: PCT/JP2023/022237

§ 371 Date: Jan. 26, 2024

(30) Foreign Application Priority Data
Jun. 21, 2022 (JP) 2022-099429
May 30, 2023 (JP) 2023-088482

(51) Int. Cl. G06F 30/13; G06T 7/73; G06T 11/20; G06T 17/00; G06T 19/20

(52) U.S. Cl. CPC G06F 30/13; G06T 7/73; G06T 11/206; G06T 17/00; G06T 19/20; G06T 2207/30184; G06T 2207/30204; G06T 2210/56; G06T 2219/2004

(57) ABSTRACT

A method of renewing a bridge includes: by a support system configured to support renewal of the bridge in which multiple deck slabs are disposed side by side in a bridge axis direction, acquiring above-deck point cloud data of an existing bridge and below-deck point cloud data of the existing bridge; combining the above-deck point cloud data and the below-deck point cloud data to create a 3D model of the existing bridge; and creating design data of a new deck slab by laying out the new deck slab by a simulation based on the 3D model of the existing bridge and a layout rule.

### TECHNICAL FIELD

The present disclosure relates to a bridge renewal method and a support system.

### BACKGROUND ART

Renewal work for renewing existing bridges has taken place. In renewal work, for example, as in Patent Literature 1, deck slabs disposed side by side in a bridge axis direction are replaced. Specifically, first, a scaffold is assembled around a bridge, and then the bridge is surveyed using the scaffold. A difference between the current bridge and an as-built drawing created at the time of construction is acquired on the basis of a survey result and the as-built drawing. Next, a designer designs new deck slabs by laying out the new deck slabs on the basis of the as-built drawing, the difference between the current bridge and the as-built drawing, and a layout rule. The new deck slabs are produced on the basis of the design of the designer, and then carried into a construction site. In the construction site, existing deck slabs are removed to expose existing girders, and then the new deck slabs carried therein are actually installed.

### CITATIONS LIST

### Patent Literature

Patent Literature 1: Japanese Laid-Open Patent Publication No. 2021-085172

### SUMMARY OF INVENTION

### Technical Problems

Since the above-described renewal work is carried out in a state in which traffic restrictions such as road closures are imposed on, for example, an expressway, traffic congestion or traffic jam occurs on roads around the site. Therefore, it is desired to shorten work periods of bridge renewal work including a period of traffic restrictions.

### Solutions to Problems

In one aspect, a method of renewing a bridge is provided. The method uses a support system configured to support renewal of the bridge in which multiple deck slabs are disposed side by side in a bridge axis direction, thereby acquiring above-deck point cloud data of an existing bridge and below-deck point cloud data of the existing bridge, combining the above-deck point cloud data and the below-deck point cloud data to create a 3D model of the existing bridge, and creating design data of a new deck slab by laying out the new deck slab by a simulation based on the 3D model of the existing bridge and a layout rule.

In another aspect, a system that supports bridge renewal includes a circuit and a memory configured to store an instruction. The circuit is configured to, upon execution of the instruction, acquire above-deck point cloud data of an existing bridge, in which multiple deck slabs are disposed side by side in a bridge axis direction, and below-deck point cloud data of the existing bridge. The circuit is also configured to, upon execution of the instruction, combine the above-deck point cloud data and the below-deck point cloud data to create a 3D model of the existing bridge. The circuit is further configured to, upon execution of the instruction, create design data of a new deck slab by laying out the new deck slab by a simulation based on the 3D model of the existing bridge and a layout rule.

### BRIEF DESCRIPTION OF DRAWINGS

FIG. 1 is a flowchart of a bridge renewal method according to an embodiment.

FIG. 2 is a diagram illustrating a schematic configuration of a support system according to an embodiment.

FIG. 3 is a diagram illustrating a hardware configuration example of an information processing apparatus.

FIG. 4 is a flowchart of a design preparation step.

FIG. 5 is a diagram schematically illustrating an example of a method of acquiring above-deck point cloud data.

FIG. 6 is a diagram schematically illustrating an example of a method of acquiring below-deck point cloud data.

FIG. 7 is a flowchart of a design step.

FIG. 8 is a diagram schematically illustrating a representative drawing of a layout draft.

FIG. 9 is a diagram schematically illustrating one of the check items of the layout draft.

FIG. 10 is a diagram schematically illustrating an example of a heat map for a new deck slab.

FIG. 11 is a diagram schematically illustrating an appearance of a finished work simulation.

FIG. 12 is a diagram schematically illustrating an appearance of field work using a construction support system.

FIG. 13 is a flowchart of a construction simulation.

FIG. 14A is a diagram schematically illustrating an appearance of the construction simulation, and is a diagram schematically illustrating an example of a state in which existing deck slabs are removed.

FIG. 14B is a diagram schematically illustrating an appearance of the construction simulation, and is a diagram illustrating an example of a state in which new deck slabs are installed.

FIG. 14C is a diagram schematically illustrating an appearance of the construction simulation, and is a diagram schematically illustrating another example of a state in which existing deck slabs are removed.

### DESCRIPTION OF EMBODIMENT

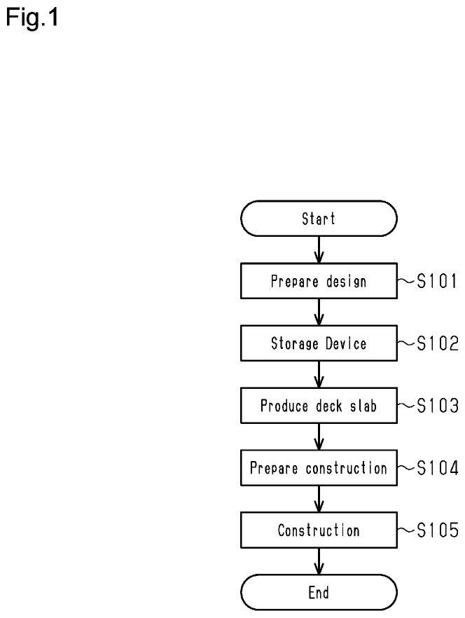

A bridge renewal method and a support system therefor according to an embodiment will be described with reference to FIGS. 1 to 12. In the present embodiment, a case in which existing deck slabs are replaced in renewal work will be described.

As illustrated in FIG. 1, a design preparation step (step S101), a design step (step S102), a deck slab production step (step S103), a construction preparation step (step S104), and a construction step (step S105) are performed in the renewal work for replacing the existing deck slab of an existing bridge.

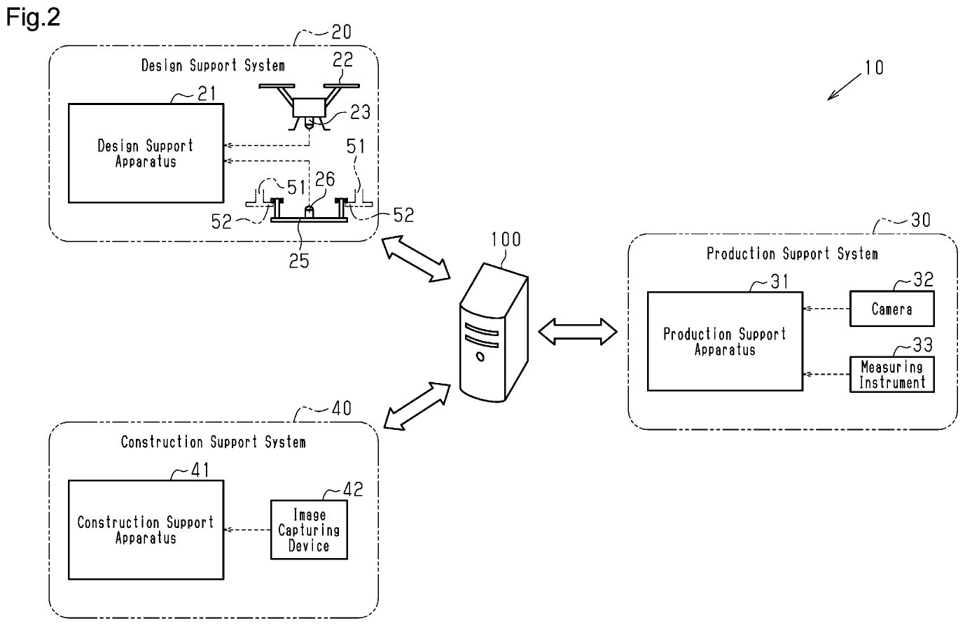

As illustrated in FIG. 2, a support system 10 that supports the renewal work includes a design support system 20, a production support system 30, and a construction support system 40. The design support system 20 is a system used by a designer who designs the renewal work. The design support system 20 includes a design support apparatus 21. The production support system 30 is a system used by a producer who produces objects to be replaced such as deck slabs. The production support system 30 includes a production support apparatus 31. The construction support system 40 is a system used by a builder who carries out the renewal work. The construction support system 40 includes a construction support apparatus 41. These support apparatuses 21, 31, and 41 are configured to communicate with each other via a server 100. That is, the respective support apparatuses 21, 31, and 41 are configured to share information uploaded to the server 100 with each other.

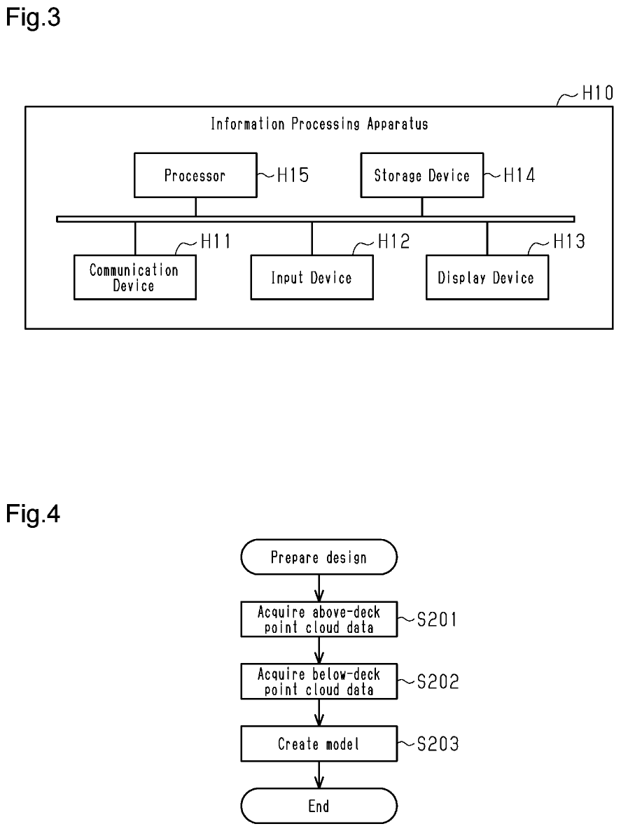

As illustrated in FIG. 3, each of the support apparatuses 21, 31, and 41 and the server 100 are mainly configured by an information processing apparatus H10.

The information processing apparatus H10 includes a communication device H11, an input device H12, a display device H13, a storage device H14, and a processor H15. This hardware configuration is an example, and the information processing apparatus H10 may include another hardware.

The communication device H11 is an interface that establishes a communication path with another apparatus to transmit and receive data. The input device H12 is a device that accepts input from an operator, and is, for example, a mouse, a keyboard, and the like. The display device H13 is a display or the like that displays various types of information. A touch panel display may be used as the input device H12 and the display device H13. The storage device H14 is a storage that stores data and various programs for executing various functions. Examples of the storage device H14 include a read-only memory (ROM), a random access memory (RAM), and a hard disk.

The processor H15 controls each process in each support apparatus using the programs and data stored in the storage device H14. Examples of the processor H15 include a central processing unit (CPU) and a microprocessor unit (MPU). The processor H15 deploys, in the RAM, the programs stored in the ROM or the like, and executes various processes. For example, when a predetermined application program is activated, the processor H15 executes each process according to the program.

The processor H15 is not limited to one that performs software processing on all processes executed by itself. For example, the processor H15 may include a dedicated hardware circuit (for example, an application specific integrated circuit: ASIC) that executes at least part of the processes executed by itself. That is, the processor H15 may be circuitry including the following:
(1) One or more processors that operate according to a computer program (software);
(2) One or more dedicated hardware circuits that execute at least part of various processes; or
(3) Circuitry including a combination thereof.

The processor H15 includes a central processing unit (CPU) and memories such as a random-access memory (RAM) and a read-only memory (ROM). The memories store program codes or commands configured to cause the CPU to execute processes. Memory or computer-readable media includes any available media that can be accessed by a general purpose or special purpose computer.

### Design Preparation Step

The design preparation step (step S101) is performed using the design support system 20. In the design preparation step, point cloud data is acquired by capturing images of the existing bridge, and construction information modeling (CIM) data of the existing bridge is created on the basis of the point cloud data. The CIM is a concept obtained by applying building information modeling (BIM) in the architectural field to the field of civil engineering, and is also known as infrastructure BIM (BIM for infrastructure), construction information management, civil infrastructure information management, civil infrastructure modeling, and the like. The point cloud data of the existing bridge includes above-deck point cloud data obtained by capturing images of the existing bridge from above and below-deck point cloud data obtained by capturing images of the existing bridge from below. Each place of the existing bridge is provided with a control point serving as a reference in combining the above-deck point cloud data and the below-deck point cloud data.

As illustrated in FIG. 4, the design preparation step includes an above-deck point cloud data acquisition step (step S201), a below-deck point cloud data acquisition step (step S202), and a model creation step (step S203).

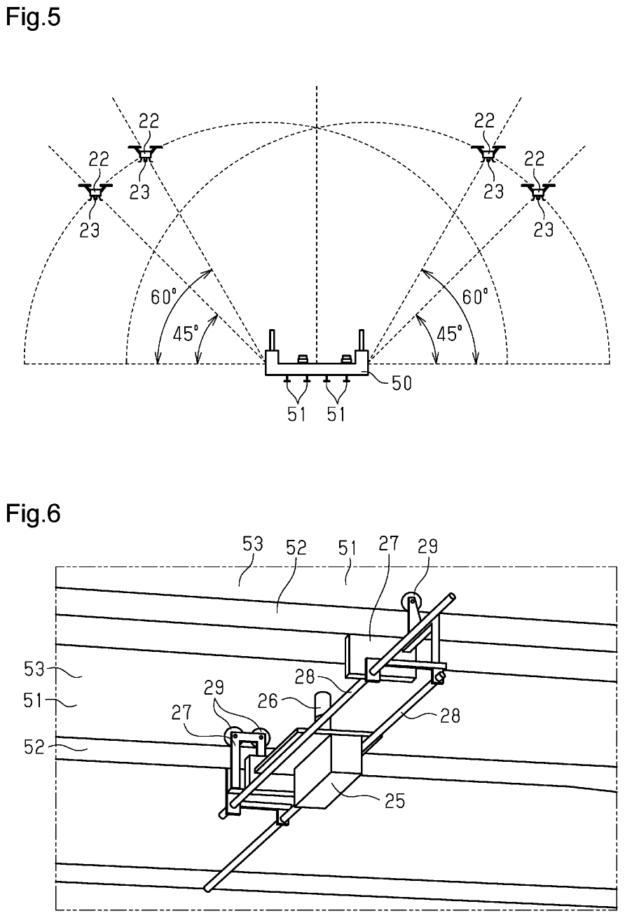

As illustrated in FIG. 5, in the above-deck point cloud data acquisition step (step S201), the above-deck point cloud data is acquired using an above-deck image capturing device 23 that is mounted on an unmanned aerial vehicle 22 whose flight area is around an existing bridge 50.

Images of a right portion of the existing bridge 50 are captured using the unmanned aerial vehicle 22 flying on the right side of the existing bridge 50. Images of a left portion of the existing bridge 50 are captured using the unmanned aerial vehicle 22 flying on the left side of the existing bridge 50. The above-deck image capturing device 23 preferably captures images at angles of 45 degrees and 60 degrees with respect to a predetermined reference point of the existing bridge 50 so as not to disturb traffic even if the unmanned aerial vehicle 22 falls. The above-deck image capturing device 23 acquires the above-deck point cloud data by capturing images of the existing bridge 50 from above while the unmanned aerial vehicle 22 is flying over the existing bridge 50. The above-deck point cloud data is input to the design support apparatus 21 when the above-deck image capturing device 23 is connected to the design support apparatus 21.

As illustrated in FIG. 6, in the below-deck point cloud data acquisition step (step S202), the below-deck point cloud data is acquired by a below-deck image capturing device 26 that is mounted on a mobile robot 25 moving along existing girders 51. The mobile robot 25 is configured to be supported by lower flanges 52 of the pair of existing girders 51 adjacent in a direction perpendicular to a bridge axis, and is configured to be movable in a bridge axis direction. The mobile robot 25 includes moving units 27 and hung members 28. For the moving units 27, rollers 29, disposed so as to sandwich a web 53 therebetween, roll on the lower flanges 52 of the existing girders 51, so that the moving units 27 move in the bridge axis direction on the lower flanges 52. The hung members 28 connect lower ends of the moving units 27 below the existing girders 51. The below-deck image capturing device 26 is mounted on the hung members 28 so as to be disposed at the center of the pair of moving units 27. The below-deck image capturing device 26 captures images of an area under a road of the existing bridge 50 while moving in the bridge axis direction by the mobile robot 25 to acquire the below-deck point cloud data of an image capturing range thereof. The below-deck point cloud data is input to the design support apparatus 21 when the below-deck image capturing device 26 is connected to the design support apparatus 21. By capturing images of the area under the road in the entire existing bridge 50, the below-deck point cloud data of the entire existing bridge 50 is acquired.

In the model creation step (step S203), the design support apparatus 21 executes a model generation process. In the model generation process, the design support apparatus 21 combines the above-deck point cloud data and the below-deck point cloud data on the basis of the control points included in each data to create the CIM data that is 3D model data for reproducing the existing bridge 50.

As described above, by acquiring the above-deck point cloud data and the below-deck point cloud data capable of creating the CIM data of the existing bridge 50 by the above-described methods, it is possible to survey the existing bridge 50 without restricting roads leading to the existing bridge 50. The above-deck point cloud data acquisition step (step S201) and the below-deck point cloud data acquisition step (step S202) may be performed in parallel. Alternatively, the below-deck point cloud data acquisition step (step S202) may be performed prior to the above-deck point cloud data acquisition step.

### Design Step

The design step (step S102) is performed using the design support system 20. In the design step, new deck slabs to be installed on the existing girders 51 are designed on the basis of the CIM data.

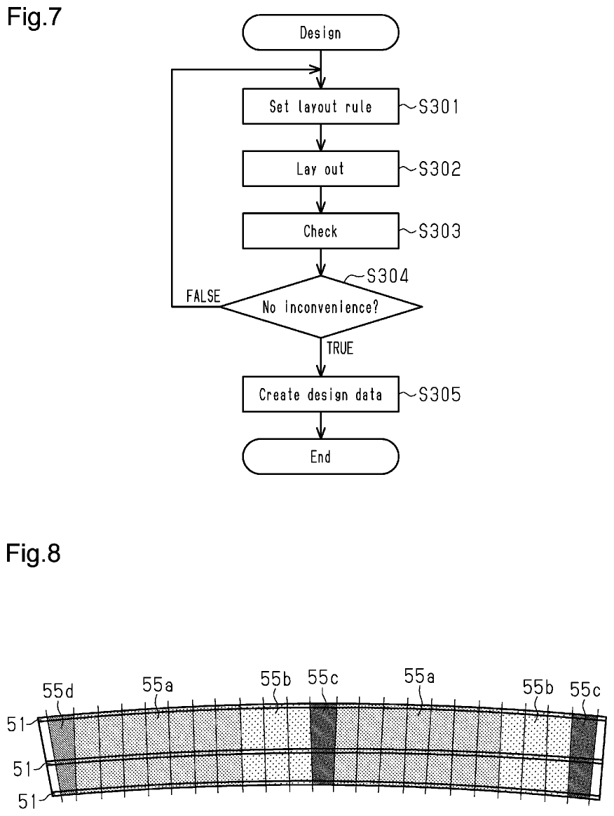

As illustrated in FIG. 7, a layout rule setting step (step S301) is performed first in the design step. In the layout rule setting step, the designer operates the design support apparatus 21 to input various types of information. The designer basically sets the layout rule such that the number of types of new deck slabs is reduced, that is, the number of new deck slabs having different shapes is reduced. The designer also sets, as the layout rule, a fixing position of a splice plate, a region where a joint portion of new deck slabs is not to be disposed, and the like in addition to basic design matters of the new deck slabs such as an entire range in which the new deck slabs are installed, materials to be used, and disposition of reinforcing bars.

A layout step (step S302) is performed next. In the layout step, the design support apparatus 21 executes a layout process. The layout process is started when the designer performs a layout start operation on the design support apparatus 21.

In the layout process, the design support apparatus 21 performs a layout simulation on the basis of the CIM data and the layout rule to lay out the new deck slabs to be installed on the existing girders 51. The design support apparatus 21 creates layout draft data indicating a layout draft that is a result of the layout simulation. The layout draft data is 3D model data capable of displaying a state in which the new deck slabs are installed on the existing girders 51.

As illustrated in FIG. 8, the display device H13 of the design support apparatus 21 displays an upper view of a state in which new deck slabs 55 are installed on the existing girders 51 as the layout draft. In addition, the new deck slabs 55 are displayed in different colors for different shapes. In FIG. 8, new deck slabs 55a, 55b, 55c, and 55d having different shapes are laid out as the new deck slabs 55, and the difference in display color is indicated by a dot difference.

When the layout process ends, a checking step is performed (step S303). In the checking step, the designer checks the layout draft. When checking the layout draft, the designer checks whether there is an inconvenience in the layout draft on the basis of the layout draft data (step S304). Specifically, the designer checks interference between reinforcing bars of adjacent deck slabs, interference between a deck slab and a splice plate, a positional relationship between a deck slab and a metal fitting of a wall railing, and the like.

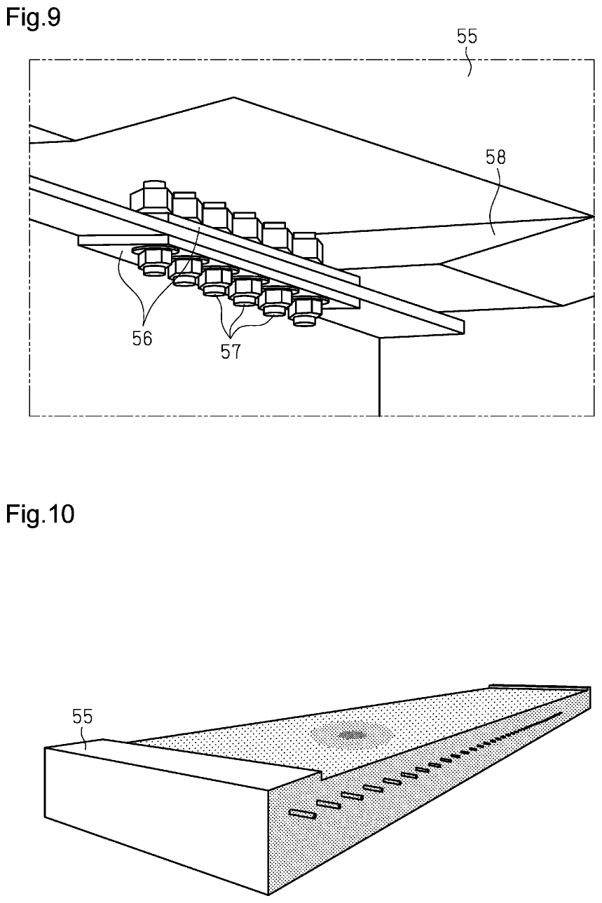

For example, as illustrated in FIG. 9, the designer checks whether a haunch part 58 of the new deck slab 55 is designed so as not to interfere with metal fittings 57 of splice plates 56.

When there is an inconvenience (step S304: FALSE), the designer corrects the layout rule, sets the layout rule again (step S301), and then causes the design support apparatus 21 to execute the layout process again (step S302). When there is no inconvenience (step S304: TRUE), a design data creation step of creating design data on the basis of the layout draft is performed (step S305).

In the design data creation step (step S305), the design support apparatus 21 creates the design data. The design data is created on the basis of the layout draft data. The design data defines identification information of each new deck slab, design coordinates indicating an installation position, materials to be used, disposition of reinforcing bars, shapes and positions of reference marks to be used at the time of checking an installation position, and the like, in addition to the 3D model data of each new deck slab. After creating the design data, the design support apparatus 21 uploads the design data to the server 100 on the basis of a sharing operation by the designer. The server 100 notifies the production support apparatus 31 of the upload of the design data.

By creating the design data in this manner, the time required for the design step is significantly shortened. In addition, by uploading the design data to the server 100, it is possible to share the design data between the designer and the producer.

### Deck Slab Production Step

The deck slab production step (step S103) is performed using the production support system 30. In the deck slab production step, the new deck slabs are produced on the basis of the design data.

The producer inputs production information of each new deck slab such as a progress and materials to be used to the production support apparatus 31. The production support apparatus 31 uploads the input production information to the server 100. In addition, a camera 32 (see FIG. 1) capable of capturing images of a production process may be installed at a production site. The camera 32 is connected to the production support apparatus 31. The production support apparatus 31 uploads image data captured by the camera 32 to the server 100 as needed. As a result, by accessing the server 100 by use of the design support apparatus 21, the designer can acquire the production information and a current situation of the production site.

The producer three-dimensionally measures each of the completed new deck slabs using a measuring instrument 33 (see FIG. 1) such as a 3D scanner. The producer inputs the identification information of the new deck slab as a measuring target and actual measurement data indicating a result of the three-dimensional measurement to the production support apparatus 31. The production support apparatus 31 creates quality record data that associates, with the identification information, a finished work error indicating a result of comparison between a shape based on the design data and a shape based on the actual measurement data and the like as well as a 3D model of the new deck slab based on the actual measurement data are associated. The quality record data is data capable of displaying a heat map of the finished work error. The production support apparatus 31 uploads the created quality record data to the server 100. The server 100 notifies the design support apparatus 21 of the upload of the quality record data. The identification information is written at a predetermined position on each of the completed new deck slabs.

### Construction Preparation Step

The construction preparation step (step S104) is performed using the design support system 20.

In the construction preparation step, the designer accesses the server 100 by using the design support apparatus 21 to perform quality confirmation of the new deck slabs to be carried into a construction site on the basis of the quality record data.

As illustrated in FIG. 10, the design support apparatus 21 displays a heat map of the new deck slab 55 on the basis of the quality record data. On the basis of this display, the designer checks in advance the finished work error of each new deck slab 55, deviation from a standard value, and the like.

Since the heat map of the finished work error of the new deck slab is displayed, the designer readily acquires a singular point of each new deck slab. In addition, in a case in which there are many new deck slabs with a large finished work error, or the like, the designer instructs the producer to improve the quality or the like by checking work contents using captured images of the camera 32 or the like in addition to the production information of the new deck slabs.

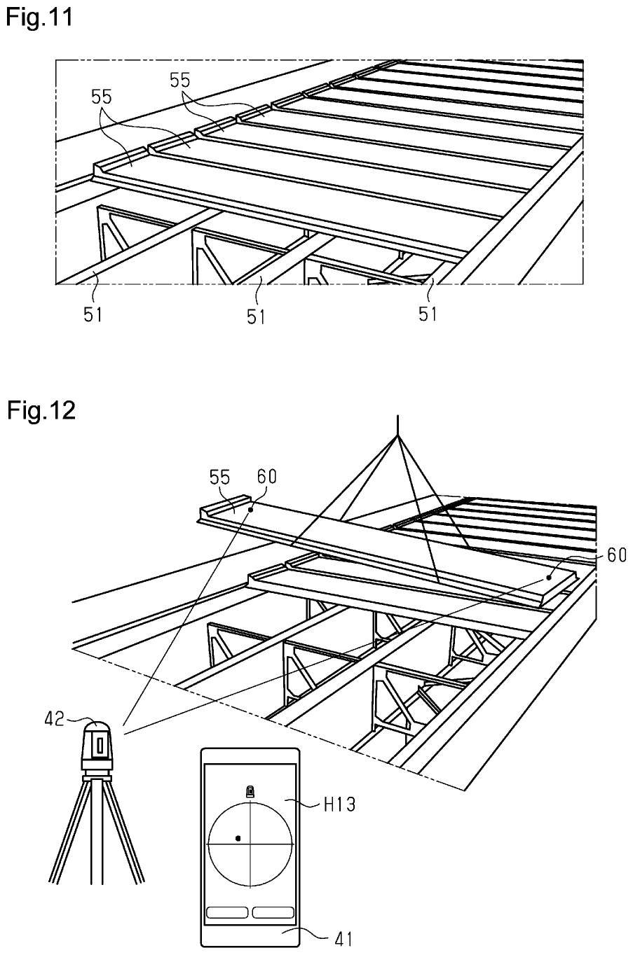

As illustrated in FIG. 11, after the quality confirmation, the design support apparatus 21 performs a finished work simulation using the quality record data of each new deck slab. In the finished work simulation, the design support apparatus 21 sequentially installs, on the existing girders 51, the 3D models of the new deck slabs 55 based on the quality record data. On the basis of a result of the finished work simulation, the designer checks interference with road accessories or the like, a cumulative error at the time of installation, a correlation error with the adjacent new deck slab 55, interference with an adjacent structure, and the like. In addition, the designer updates the design data by performing a pre-construction correction simulation of correcting the design coordinates of the new deck slabs on the basis of the result of the finished work simulation by using the design support apparatus 21.

By performing the finished work simulation on the basis of the quality record data as described above, it is possible to avoid in advance a defect at the time of construction caused by the finished work error. In addition, since the quality of the new deck slabs is acquired in advance, the designer can instruct the producer to improve the quality or the like.

### Construction Step

In the construction step (step S105), the builder actually sequentially installs the new deck slabs. The builder sequentially installs the respective new deck slabs at corresponding installation positions by lifting the new deck slabs with lifting equipment such as a crane. The builder installs the new deck slabs while checking a position of the new deck slab being lifted by using the construction support system 40. The builder refers to a person involved in installation work of the new deck slabs.

As illustrated in FIG. 12, the construction support system 40 includes the construction support apparatus 41 and an image capturing device 42. The construction support apparatus 41 and the image capturing device 42 are configured to communicate with each other. The construction support apparatus 41 is preferably a portable machine that can be carried by the builder, and preferably includes at least the display device H13 that can be carried by the builder.

In the construction step, the builder installs the image capturing device 42 such that the installation position of the new deck slab 55 is included in an image capturing range. After installing the image capturing device 42, the builder inputs image capturing coordinates indicating a position of the image capturing device 42 to the construction support apparatus 41. On the basis of the design data, the builder also inputs the identification information of the new deck slab 55 to be installed next, to the construction support apparatus 41.

When the new deck slab 55 being lifted is carried to the vicinity of the installation position, the builder who has input the image capturing coordinates and the identification information starts capturing images using the image capturing device 42. The image capturing device 42 transmits captured image data to the construction support apparatus 41 as needed.

The construction support apparatus 41 performs image processing on the image data transmitted by the image capturing device 42 to acquire relative coordinates of the new deck slab 55 with respect to the image capturing device 42 on the basis of reference marks 60 of the new deck slab 55 included in the image data. The construction support apparatus 41 acquires current position coordinates of the new deck slab 55 on the basis of the relative coordinates and the image capturing coordinates, and then displays an image including the design coordinates and the current position coordinates on the display device H13. A display example of the image including the design coordinates and the current position coordinates is illustrated on the display device H13 in FIG. 12. The construction support apparatus 41 displays the image indicating the current position coordinates in a horizontal coordinate system centered on the design coordinates. The builder performs position adjustment of the new deck slab 55 on the basis of such an image and installs the new deck slab 55.

When the builder inputs installation completion after the installation of the new deck slab 55, the construction support apparatus 41 transmits installation coordinates indicating a position where the new deck slab 55 is actually installed to the design support system 20. The design support apparatus 21 stores the installation coordinates of the new deck slab 55 in the server 100 as installation coordinate data.

When the installation coordinate data is stored, the design support apparatus 21 performs a construction correction simulation of correcting the design coordinates of the new deck slabs 55 to be installed in the next and subsequent operations on the basis of the installation coordinate data and the design data. The builder installs the new deck slabs 55 in the next and subsequent operations on the basis of the corrected design coordinates. In this way, the new deck slabs 55 are sequentially installed.

When all the new deck slabs 55 are installed and the designer inputs completion, construction data is created in which the quality record data, the installation coordinate data, and the like of each of the new deck slabs 55 are added to the design data. The construction data is submitted to the construction orderer upon completion of the work, and is used for maintenance management of the bridge.

Operations and advantages of the present embodiment will be described.
(1) According to the above embodiment, the CIM data capable of reproducing the existing bridge 50 is created on the basis of the above-deck point cloud data acquired using the unmanned aerial vehicle 22 and the below-deck point cloud data acquired using the mobile robot 25. As a result, the existing bridge 50 can be surveyed without restricting roads leading to the existing bridge 50, so that a work period of the renewal work is shortened.
(2) According to the above embodiment, the new deck slabs 55 are laid out on the existing girders 51 by the layout simulation based on the CIM data. As a result, the time required for designing the new deck slabs 55 is shortened, so that the work period of the renewal work is shortened.
(3) According to the above embodiment, the designer acquires in advance the finished work error of the new deck slab 55 produced by the producer. As a result, a defect caused by the finished work error is less likely to occur at the time of actual construction, so that the work period of the renewal work is shortened.
(4) In addition, the design support apparatus 21 displays the heat map of the finished work error of the new deck slab 55, so that the designer readily acquires the singular point of each new deck slab 55. As a result, it is possible to shorten a time for considering how to deal with the finished work error.
(5) In the above embodiment, the finished work simulation in which the new deck slabs 55 are installed on the existing girders 51 is performed on the basis of the CIM data and the actual measurement data. As a result, it is possible to check, with high reliability, interference with road accessories, a cumulative error at the time of installation, a correlation error with an adjacent member, interference with an adjacent structure, and the like. In addition, it is possible to produce a new deck slab 55 if the already produced new deck slab 55 is confirmed to be difficult to install before construction. As a result, the defect caused by the finished work error is further less likely to occur at the time of actual construction.
(6) In the above embodiment, the new deck slab 55 is installed on the basis of the design coordinates and the current position coordinates displayed on the display device H13 of the construction support system 40. As a result, the time required for installing the new deck slab 55 is shortened, and the new deck slab 55 is installed with high positional accuracy. In addition, the builder does not need to approach the new deck slab 55 being lifted for position measurement or the like, and thus, the safety of the builder is also be ensured.
(7) According to the above embodiment, coordinate management of the design coordinates of the new deck slabs 55 to be subsequently installed is performed on the basis of the installation coordinates of the new deck slab 55 that has already been installed. As a result, the defect is less likely to occur at the time of actual construction.

The above-described embodiment may be modified as follows. The above-described embodiment and the following modifications can be combined as long as the combined modifications remain technically consistent with each other.

In the above embodiment, the bridge renewal method and the support system have been described using renewal of deck slabs. The bridge renewal method and the support system are not limited thereto, and may be applied to a renewal target member that is a target of renewal, such as a wall railing installed along end portions of the deck slabs.

In the above embodiment, the adjustment of the installation positions of the new deck slabs 55 is not limited to the method using the image capturing device 42. For example, the adjustment may be performed on the basis of visual observation or the like by the builder.

In the above embodiment, the new deck slabs 55 are installed after performing the finished work simulation. The present disclosure is not limited thereto, and the new deck slabs 55 may be installed without performing the finished work simulation.

In the above embodiment, the heat map of the new deck slab 55 is displayed on the basis of the actual measurement data. The present disclosure is not limited thereto. The actual measurement data may be any data that allows for shape recognition of the new deck slab 55, and it is not always necessary to display the heat map.

In the above embodiment, the above-deck point cloud data is acquired using the above-deck image capturing device 23 mounted on the unmanned aerial vehicle 22. The present disclosure is not limited thereto, and the above-deck point cloud data may be acquired using, for example, an image capturing device installed near the existing bridge 50 and capable of capturing images of the road of the existing bridge 50. In addition, the above-deck point cloud data may be acquired using a laser measuring instrument mounted on the unmanned aerial vehicle 22, or may be acquired using a laser measuring instrument installed near the existing bridge 50. Furthermore, the above-deck point cloud data may be acquired on the basis of an image capturing result by the image capturing device and a measurement result by the laser measuring instrument.

In the above embodiment, the below-deck point cloud data is acquired using the below-deck image capturing device 26 mounted on the mobile robot 25. The present disclosure is not limited thereto, and the below-deck point cloud data may be acquired using, for example, an image capturing device mounted on an unmanned aerial vehicle. In addition, the below-deck point cloud data may be acquired using a laser measuring instrument mounted on the unmanned aerial vehicle, or may be acquired using a laser measuring instrument installed near the existing bridge 50. Furthermore, the below-deck point cloud data may be acquired on the basis of an image capturing result by the image capturing device and a measurement result by the laser measuring instrument.

In the above embodiment, a construction simulation using the CIM data and the design data may be performed for the renewal work. The construction simulation visualizes a construction procedure of the renewal work with 3D models by putting the 3D models on a time axis. The construction simulation is used, for example, when the designer decides a construction plan.

The server 100 performs various processes related to the construction simulation. The server 100 executes various processes related to the construction simulation when a predetermined operation is performed in the design support apparatus 21 that is accessing the server 100. In this processing, the server 100 provides the design support apparatus 21 accessing the server 100 with an input screen for inputting various types of information including a start of the construction simulation.

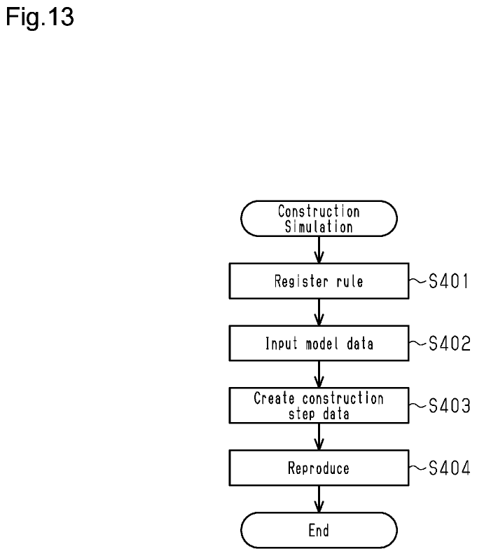

As illustrated in FIG. 13, as the processes related to the construction simulation, the server 100 executes a rule registration process (step S401), a model data input process (step S402), a construction step data creation process (step S403), and a reproduction process (step S404).

The rule registration process (step S401) is a process of registering a construction procedure rule. The designer registers the construction procedure rule. The server 100 provides the design support apparatus 21 accessing the server 100 with a rule registration screen for registering the construction procedure rule when a predetermined operation is performed in the design support apparatus 21. The designer inputs the construction procedure rule to the rule registration screen using the design support apparatus 21.

As the construction procedure rule, the designer inputs a rule related to a construction cycle. The rule related to the construction cycle defines the number of removed existing deck slabs and a removal work period, and the number of installed new deck slabs 55 and an installation work period in one cycle by setting the removal of the existing deck slabs and the installation of the new deck slabs 55 as one cycle of construction. In addition, for example, the designer inputs a start date and time, a start direction, and the like as the construction procedure rule.

Preferably, the server 100 stores the input construction procedure rule in a readable manner. This allows the designer to create a new construction procedure rule by changing a part of a construction procedure rule based on similar renewal work.

The model data input process (step S402) is a process executed when the CIM data or the design data is uploaded to the server 100 from the design support apparatus 21. The server 100 provides a data input screen to the design support apparatus 21 accessing the server 100 when a predetermined operation is performed in the design support apparatus 21. The designer uploads the CIM data or the design data to the server 100 by using the data input screen accessed by the design support apparatus 21. The server 100 stores the uploaded various data in a predetermined recording area.

The construction step data creation process (step S403) is a process of creating construction step data on the basis of the construction procedure rule, the CIM data, and the design data. In the construction step data creation process, the server 100 creates, as the construction step data, data in which identification information, a start date and time, an end date and time, and the like are defined for each 3D model as a construction target on the basis of the construction procedure rule, the CIM data, and the design data.

The reproduction process (step S404) is a process of reproducing the construction procedure with the 3D models on the basis of the CIM data, the design data, and the construction step data. The server 100 executes the reproduction process when a reproduction operation is performed in the design support apparatus 21 accessing the server 100.

In the reproduction process, the server 100 displays or hides the 3D model indicated by the CIM data or the design data on the basis of the construction step data.

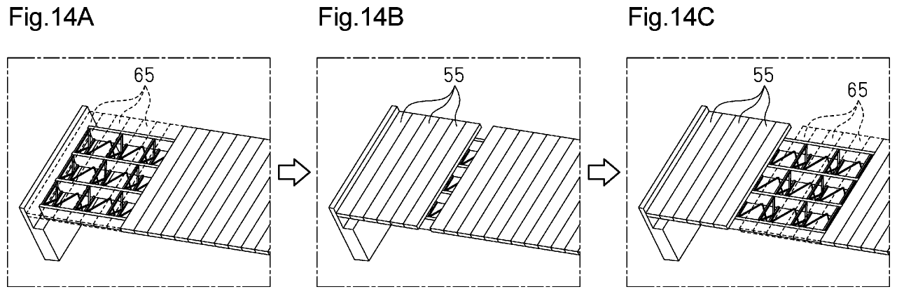

For example, in the reproduction process, the server 100 hides existing deck slabs 65 as illustrated in FIG. 14A, and then displays the new deck slabs 55 in a space made by hiding the existing deck slabs 65 as illustrated in FIG. 14B. Thereafter, as illustrated in FIG. 14C, the server 100 hides existing deck slabs 65 adjacent to the new deck slabs 55.

As described above, in the reproduction process, the existing deck slab 65 is hidden or the new deck slab 55 is displayed according to the lapse of time, whereby the construction procedure of the renewal work is visualized with the 3D models. In the reproduction process, a 3D model of lifting equipment used for removing the existing deck slab 65 and installing the new deck slab 55 may be displayed. The designer decides the construction plan on the basis of a result of such a construction simulation.

The construction simulation is preferably executable by the information processing apparatus that can access the server 100, such as the production support apparatus 31 and the construction support apparatus 41. According to such a configuration, the designer can use his/her own information processing apparatus when explaining the construction plan to the construction orderer.

1. A method of renewing a bridge, the method comprising:
by a support system configured to support renewal of the bridge in which multiple deck slabs are disposed side by side in a bridge axis direction,
acquiring above-deck point cloud data of an existing bridge and below-deck point cloud data of the existing bridge;
combining the above-deck point cloud data and the below-deck point cloud data to create a 3D model of the existing bridge; and
creating design data of a new deck slab by laying out the new deck slab by a simulation based on the 3D model of the existing bridge and a layout rule.

2. The method according to claim 1, further comprising
acquiring, by the support system, actual measurement data of the new deck slab produced based on the design data before the new deck slab is carried into a construction site, wherein the actual measurement data is acquired by three-dimensional measurement of the new deck slab.

3. The method according to claim 2, further comprising
displaying, by the support system, a heat map of the new deck slab based on the actual measurement data.

4. The method according to claim 2, further comprising
performing, by the support system, a simulation of installing the new deck slab on an existing girder based on the 3D model of the existing bridge and the actual measurement data of the new deck slab.

5. The method according to claim 1, wherein
the new deck slab is provided with multiple reference marks, and
the design data includes design coordinates indicating an installation position of the new deck slab, the method further comprising:
by the support system,
acquiring installation coordinates indicating a position where the new deck slab is actually installed on an existing girder based on image data obtained by capturing images of the multiple reference marks of the new deck slab in a state in which the new deck slab is actually installed on the existing girder; and
performing a simulation of correcting design coordinates of a subsequent new deck slab in the design data based on the installation coordinates.

6. The method according to claim 1, wherein
the design data includes a 3D model of the new deck slab, the method further comprising
performing, by the support system, a simulation of replacing the deck slab by using the 3D model of the existing bridge and the 3D model of the new deck slab.

7. A system that supports bridge renewal, the system comprising:
a circuit; and
a memory configured to store an instruction, wherein
the circuit is configured to, upon execution of the instruction:
acquire above-deck point cloud data of an existing bridge, in which multiple deck slabs are disposed side by side in a bridge axis direction, and below-deck point cloud data of the existing bridge;
combine the above-deck point cloud data and the below-deck point cloud data to create a 3D model of the existing bridge; and
create design data of a new deck slab by laying out the new deck slab by a simulation based on the 3D model of the existing bridge and a layout rule.

8. The system according to claim 7, wherein
the circuit is further configured to acquire, by the support system, actual measurement data of the new deck slab produced based on the design data before the new deck slab is carried into a construction site, and the actual measurement data is acquired by three-dimensional measurement of the new deck slab.

9. The system according to claim 8, wherein
the circuit is further configured to display a heat map of the new deck slab based on the actual measurement data.

10. The system according to claim 8, wherein
the circuit is further configured to perform a simulation of installing the new deck slab on an existing girder based on the 3D model of the existing bridge and the actual measurement data of the new deck slab.

11. The system according to claim 7, wherein
the new deck slab is provided with multiple reference marks,
the design data includes design coordinates indicating an installation position of the new deck slab, and
the circuit is further configured to:
acquire installation coordinates indicating a position where the new deck slab is actually installed on an existing girder based on image data obtained by capturing images of the multiple reference marks of the new deck slab in a state in which the new deck slab is actually installed on the existing girder; and
perform a simulation of correcting design coordinates of a subsequent new deck slab in the design data based on the installation coordinates.

12. The system according to claim 7, wherein
the design data includes a 3D model of the new deck slab, and
the circuit is further configured to perform a simulation of replacing the deck slab by using the 3D model of the existing bridge and the 3D model of the new deck slab.
